(19) United States
(12) Patent Application Publication
(10) Pub. No.: US 2017/0321023 A1
(43) Pub. Date: Nov. 9, 2017

(54) Barium Titanate Particles Incorporated in Polyetherimide Based Composite Films with Enhanced Remnant Polarization and Methods of Making Same

(71) Applicant: Sabic Global Technologies, B.V., Bergen Op Zoom (NL)

(72) Inventors: Wazed ALI, New Delhi (IN); Redha BELLA, Riyadh (SA); Theo HOEKS, Bergen op Zoom (NL); Susanta MITRA, Bangalore (IN)

(21) Appl. No.: 15/496,664

(22) Filed: Apr. 25, 2017

Related U.S. Application Data
(60) Provisional application No. 62/332,714, filed on May 6, 2016.

(51) Int. Cl. C08J 5/18; H01L 41/187; C08K 3/22; B29C 39/42; C08K 9/04; H01L 41/35; B29C 39/00; B29L 31/34; B29K 79/00; B29K 105/00

(52) U.S. Cl. CPC C08J 5/18; H01L 41/35; H01L 41/1871; C08K 3/22; B29C 39/42; B29C 39/003; C08K 9/04; C08J 2379/08; B29L 2031/3475; B29K 2079/085; B29K 2105/0005; C08K 2003/2206; C08K 2003/2237

(57) ABSTRACT

A method of making a solvent cast polymer composite film comprising (a) contacting barium titanate, a titanate coupling agent (TCA) and a mixing solvent to form a barium titanate and TCA solution; (b) dispersing at least a portion of the barium titanate and TCA solution to form TCA treated barium titanate; (c) contacting at least a portion of the TCA treated barium titanate with a polyetherimide and a casting solvent to form a polymer composite casting solution; (d) casting at least a portion of the polymer composite casting solution onto a casting substrate to form a solvent cast polymer composite solution; and (e) curing at least a portion of the solvent cast polymer composite solution to form the solvent cast polymer composite film.

### CROSS REFERENCE TO RELATED APPLICATIONS

The present application is a non-provisional of and claims priority to U.S. Provisional Patent Application No. 62/332,714 filed May 6, 2016 and entitled “Barium Titanate Particles Incorporated in Polyetherimide Based Composite Films with Enhanced Remnant Polarization and Methods of Making Same,” which application is incorporated by reference herein in its entirety.

### TECHNICAL FIELD

The present disclosure relates to methods of making polymer composite films, more specifically methods of making solvent cast polyetherimide films comprising barium titanate particles.

### BACKGROUND

Electrostatic film capacitors with high volumetric energy density are important components for a variety of electronic devices. Generally, capacitors are energy-storing devices having two parallel conductive plates separated by a thin layer of an insulating (dielectric) film. When a voltage is applied across the plates, the electric field in the dielectric displaces electric charges, and thus stores energy. The amount of energy stored by a capacitor depends on the dielectric constant of the insulating material, the applied voltage, and the dimensions (total area and thickness) of the film. Consequently, in order to maximize the total amount of energy that a capacitor can accumulate, a dielectric constant and breakdown voltage of the film need to be maximized. The physical characteristics of the dielectric material in a capacitor are the primary determining factors for the performance of the capacitor, so improvements in one or more of the physical properties of the dielectric material of a capacitor can result in corresponding performance improvements in the capacitor component, usually resulting in performance and lifetime enhancements of the electronics system or product in which the capacitor is embedded.

Barium titanate is a class of ceramic based materials which has high dielectric constant, and as such could be used for improving the properties of capacitor films. However, barium titanate has high specific gravity, and a suitable dispersion of barium titanate particles into polymer matrices is very difficult to achieve, especially in films prepared by a solvent cast process where most of the particles tend to settle to the bottom of the film. A mostly non-uniform distribution of barium titanate particles in a polymer matrix leads to poor dielectric stability and early breakage in a location where the particle concentration is higher as compared to another area. Thus, there is an ongoing need for the development of methods for preparing polymeric films containing an uniform distribution of barium titanate particles.

### BRIEF SUMMARY

Disclosed herein is a method of making a solvent cast polymer composite film comprising (a) contacting barium titanate, a titanate coupling agent (TCA) and a mixing solvent to form a barium titanate and TCA solution, (b) dispersing at least a portion of the barium titanate and TCA solution to form TCA treated barium titanate, (c) contacting at least a portion of the TCA treated barium titanate with a polyetherimide and a casting solvent to form a polymer composite casting solution, (d) casting at least a portion of the polymer composite casting solution onto a casting substrate to form a solvent cast polymer composite solution, and (e) curing at least a portion of the solvent cast polymer composite solution to form the solvent cast polymer composite film.

Also disclosed herein is a solvent cast polymer composite film comprising a titanate coupling agent (TCA) treated barium titanate and polyetherimide, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy.

Further disclosed herein is a method of making a solvent cast polymer composite film comprising (a) contacting barium titanate and a titanate coupling agent (TCA) to form TCA treated barium titanate, (b) contacting at least a portion of the TCA treated barium titanate with a polyetherimide and a casting solvent to form a polymer composite casting solution, and (c) casting at least a portion of the polymer composite casting solution to form the solvent cast polymer composite film, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy.

### BRIEF DESCRIPTION OF THE DRAWINGS

For a detailed description of the preferred embodiments of the disclosed methods, reference will now be made to the accompanying drawing in which:

FIG. 1 displays a process flow sequence for preparing titanate coupling agent (TCA) treated barium titanate;

FIG. 2 displays Fourier transform infrared spectroscopy (FTIR) spectra of untreated barium titanate and TCA treated barium titanate;

FIG. 3 displays thermogravimetric analysis (TGA) curves of untreated barium titanate and TCA treated barium titanate;

FIGS. 4-1 and 4-2 display scanning electron microscopy (SEM) images of polymer films comprising untreated barium titanate and TCA treated barium titanate;

FIG. 5 displays SEM images of cross-sections of films comprising untreated barium titanate and TCA treated barium titanate; and

FIG. 6 displays polarization curves for gold/palladium sputter coated polymer films comprising untreated barium titanate and TCA treated barium titanate.

### DETAILED DESCRIPTION

Disclosed herein are solvent cast polymer composite films comprising a titanate coupling agent (TCA) treated barium titanate and polyetherimide, and methods of making same. In an embodiment, a solvent cast polymer composite film can comprise a TCA treated barium titanate and polyetherimide, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy (SEM). In such embodiment, the solvent cast polymer composite films can be piezoelectric.

In an embodiment, a method of making a solvent cast polymer composite film can comprise (a) contacting barium titanate, a TCA and a mixing solvent to form a barium titanate and TCA solution; (b) dispersing at least a portion of the barium titanate and TCA solution to form TCA treated barium titanate; (c) contacting at least a portion of the TCA treated barium titanate with a polyetherimide and a casting solvent to form a polymer composite casting solution; (d) casting at least a portion of the polymer composite casting solution onto a casting substrate to form a solvent cast polymer composite solution; and (e) curing at least a portion of the solvent cast polymer composite solution to form the solvent cast polymer composite film. In such embodiment, the step (b) of dispersing at least a portion of the barium titanate and TCA solution can comprise sonicating the at least a portion of the barium titanate and TCA solution.

Other than in the operating examples or where otherwise indicated, all numbers or expressions referring to quantities of ingredients, reaction conditions, and the like, used in the specification and claims are to be understood as modified in all instances by the term “about.” Various numerical ranges are disclosed herein. Because these ranges are continuous, they include every value between the minimum and maximum values. The endpoints of all ranges reciting the same characteristic or component are independently combinable and inclusive of the recited endpoint. Unless expressly indicated otherwise, the various numerical ranges specified in this application are approximations. The endpoints of all ranges directed to the same component or property are inclusive of the endpoint and independently combinable. The term “from more than 0 to an amount” means that the named component is present in some amount more than 0, and up to and including the higher named amount.

The terms “a,” “an,” and “the” do not denote a limitation of quantity, but rather denote the presence of at least one of the referenced item. As used herein the singular forms “a,” “an,” and “the” include plural referents.

As used herein, “combinations thereof” is inclusive of one or more of the recited elements, optionally together with a like element not recited, e.g., inclusive of a combination of one or more of the named components, optionally with one or more other components not specifically named that have essentially the same function. As used herein, the term “combination” is inclusive of blends, mixtures, alloys, reaction products, and the like.

Reference throughout the specification to “an embodiment,” “another embodiment,” “other embodiments,” “some embodiments,” and so forth, means that a particular element (e.g., feature, structure, property, and/or characteristic) described in connection with the embodiment is included in at least an embodiment described herein, and may or may not be present in other embodiments. In addition, it is to be understood that the described element(s) can be combined in any suitable manner in the various embodiments.

As used herein, the terms “inhibiting” or “reducing” or “preventing” or “avoiding” or any variation of these terms, include any measurable decrease or complete inhibition to achieve a desired result.

As used herein, the term “effective,” means adequate to accomplish a desired, expected, or intended result.

As used herein, the terms “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”) are inclusive or open-ended and do not exclude additional, unrecited elements or method steps.

Unless defined otherwise, technical and scientific terms used herein have the same meaning as is commonly understood by one of skill in the art.

Compounds are described herein using standard nomenclature. For example, any position not substituted by any indicated group is understood to have its valency filled by a bond as indicated, or a hydrogen atom. A dash (“-”) that is not between two letters or symbols is used to indicate a point of attachment for a substituent. For example, —CHO is attached through the carbon of the carbonyl group.

In an embodiment, a method of making a solvent cast polymer composite film can comprise contacting barium titanate (BaTiO₃) and a titanate coupling agent (TCA) to form TCA treated barium titanate. Barium titanate and TCA can be contacted by using any suitable methodology to form the TCA treated barium titanate. Generally, a TCA refers to a compound that can couple, bind, adhere, and the like, or combinations thereof to a titanate.

In an embodiment, the TCA can comprise neoalkoxy titanates, monoalkoxy titanates, oxyacetate chelate titanates, cycloheteroatom titanates, ethylene chelate titanates, coordinate titanates, and the like, or combinations thereof. In an embodiment, the neoalkoxy titanates can comprise titanium (IV) 2,2(bis 2-propenolatomethyl)butanolato, tris(dioctyl)phosphato-O (neopentyl(diallyl)oxy, tri(dioctyl)phoshato titanate).

In an embodiment, the barium titanate can comprise barium titanate particles, wherein the barium titanate particles can have an average size of from about 100 nm to about 2 microns, alternatively from about 100 nm to about 900 nm, or alternatively from about 200 nm to about 800 nm. As will be appreciated by one of skill in the art, and with the help of this disclosure, certain polymeric film applications may impose certain particle size restrictions. For example, some transparent polymeric films require (for transparency) that the size of the particles contained in the film be less than about 800 nm.

In an embodiment, barium titanate, a TCA and a mixing solvent can be contacted (e.g., mixed together) to form a barium titanate and TCA solution. In some embodiments, the components (e.g., BaTiO₃, TCA, mixing solvent) of the barium titanate and TCA solution can be mixed together at the same time (e.g., concurrently). In other embodiments, the components of the barium titanate and TCA solution can be mixed with each other sequentially. For example, the TCA can be dissolved in the mixing solvent to form a solution of TCA in the mixing solvent, and barium titanate can be added to the solution of TCA in the mixing solvent to form the barium titanate and TCA solution.

In an embodiment, the components (e.g., BaTiO₃, TCA, mixing solvent) of the barium titanate and TCA solution can be mixed together in any suitable order under agitation, such as for example under stirring, magnetic stirring, etc. In an embodiment, barium titanate can be added to the solution of TCA in the mixing solvent under magnetic stirring to form the barium titanate and TCA solution.

Nonlimiting examples of mixing solvents suitable for use in the present disclosure include a polar solvent, an alcohol, methanol, ethanol, propanol, isopropanol (IPA), butanol, pentanol, and the like, or combinations thereof.

In an embodiment, the solution of TCA in the mixing solvent can comprise TCA in an amount of from about 0.1% to about 5%, alternatively from about 0.5% to about 2.5%, or alternatively from about 1% to about 2%, based on the total weight of the barium titanate (e.g., the barium titanate in a barium titanate and TCA solution).

In an embodiment, the barium titanate and TCA solution can comprise TCA in an amount of from about 0.05 wt. % to about 5 wt. %, alternatively from about 0.1 wt. % to about 2.5 wt. %, or alternatively from about 0.2 wt. % to about 1 wt. %, based on the total weight of the barium titanate.

In an embodiment, at least a portion of the barium titanate and TCA solution can be dispersed to form a TCA treated barium titanate solution, wherein the TCA treated barium titanate solution comprises TCA treated barium titanate, uncoupled TCA, and mixing solvent. By dispersing the barium titanate and TCA solution, an uniform distribution of both TCA and barium titanate in solution can be achieved, thereby facilitating interactions between TCA and barium titanate. Without wishing to be limited by theory, TCA can couple to barium titanate via electrostatic interactions, or other physical interactions (e.g., physical bonds) and/or chemical interactions (e.g., chemical bonds, a covalent bonds, etc.). Generally, not all TCA will couple to the barium titanate, and as such some uncoupled TCA will be present in the TCA treated barium titanate solution.

In an embodiment, the barium titanate and TCA solution can be dispersed for a time period of from about 5 minutes to about 3 hours, alternatively from about 10 minutes to about 2 hours, alternatively from about 20 minutes to about 1 hour. In an embodiment, the barium titanate and TCA solution can be dispersed for an amount of time effective to facilitate the formation of TCA treated barium titanate.

In an embodiment, dispersing at least a portion of the barium titanate and TCA solution can comprise sonicating the at least a portion of the barium titanate and TCA solution. Without wishing to be limited by theory, sonicating a solution comprising barium titanate and TCA can create localized vibrations that can further create interactions between barium titanate and TCA, thereby facilitating coupling of the TCA to the barium titanate.

In some embodiments, the sonicated barium titanate and TCA solution can be further stirred (e.g., magnetically stirred, agitated) for a time period of from about 15 minutes to about 6 hours, alternatively from about 30 minutes to about 4 hours, alternatively from about 1 hour to about 2 hours. Without wishing to be limited by theory, stirring the sonicated barium titanate and TCA solution may allow for more TCA coupling to barium titanate.

In some embodiments, the sonicated and optionally stirred barium titanate and TCA solution can be allowed to air dry to produce a raw TCA treated barium titanate, for example at ambient pressure and temperature, for a time period of from about 6 hours to about 48 hours, alternatively from about 8 hours to about 24 hours, alternatively from about 10 hours to about 16 hours. As will be appreciated by one of skill in the art, and with the help of this disclosure, air drying the sonicated and optionally stirred barium titanate and TCA solution provides an opportunity for a portion of the mixing solvent to evaporate.

In other embodiments, at least a portion of the TCA treated barium titanate solution can be filtered to yield a raw TCA treated barium titanate and a first spent mixing solvent, wherein the raw TCA treated barium titanate comprises TCA treated barium titanate and uncoupled TCA, and wherein the first spent mixing solvent comprises a portion of the uncoupled TCA of the TCA treated barium titanate solution.

In an embodiment, the raw TCA treated barium titanate can be washed with mixing solvent (e.g., on a filter where the raw TCA treated barium titanate was filtered out from the TCA treated barium titanate solution) to yield the TCA treated barium titanate and a second spent mixing solvent, wherein the second spent mixing solvent comprises at least a portion of the uncoupled TCA of the raw TCA treated barium titanate.

In an embodiment, the first spent mixing solvent and/or the second spent mixing solvent comprising TCA can be recycled to a step of adding barium titanate to the solution of TCA in the mixing solvent to form the barium titanate and TCA solution, wherein additional TCA can be optionally added to the first spent mixing solvent and/or the second spent mixing solvent, depending on the concentration of TCA in the first spent mixing solvent and/or the second spent mixing solvent.

In an embodiment, the raw TCA treated barium titanate and/or the TCA treated barium titanate can be further dried and/or used to make the polymer composite films comprising TCA treated barium titanate. The raw TCA treated barium titanate and/or the TCA treated barium titanate can be dried at a temperature that is effective to remove the mixing solvent wherein such temperature is low enough as to not disrupt the coupling between the TCA and the barium titanate. Generally, such drying can be achieved under vacuum. As will be appreciated by one of skill in the art, and with the help of this disclosure, the drying temperature is dependent on a variety of factors, such as the mixing solvent used, the TCA used, etc.

In an embodiment, the raw TCA treated barium titanate and/or the TCA treated barium titanate can be dried at a temperature of from about 50° C. to about 120° C., alternatively from about 60° C. to about 110° C., or alternatively from about 70° C. to about 100° C., and under vacuum.

In an embodiment, the raw TCA treated barium titanate and/or the TCA treated barium titanate can be dried for a time period of from about 1 hour to about 24 hours, alternatively from about 2 hours to about 12 hours, alternatively from about 4 hours to about 8 hours.

In an embodiment, the TCA treated barium titanate (e.g., raw TCA treated barium titanate and/or TCA treated barium titanate) can comprise TCA in an amount of from about 0.01 wt. % to about 1 wt. %, alternatively from about 0.1 wt. % to about 0.75 wt. %, or alternatively from about 0.15 wt. % to about 0.5 wt. %, based on the total weight of the barium titanate.

In an embodiment, a method of making a solvent cast polymer composite film can comprise contacting at least a portion of the TCA treated barium titanate with a polyetherimide (PEI) and a casting solvent to form a polymer composite casting solution. The PEI can comprise PEI polymers (e.g., PEI homopolymers) and/or PEI copolymers (e.g., polyetherimide sulfones). Nonlimiting examples of PEIs suitable for use in the present disclosure include ULTEM resin, EXTEM resin, SILTEM resin, and the like, or combinations thereof, all of which are commercially available from SABIC Innovative Plastics. PEIs suitable for use in the present disclosure are described in more detail in U.S. Patent Application No. 20130143018 A1, which is incorporated by reference herein in its entirety. While the present disclosure will be discussed in detail in the context of PEI films, it should be understood that the methods disclosed herein can be used in conjunction with any polymers compatible with the methods and materials disclosed herein.

Nonlimiting examples of casting solvents suitable for use in the present disclosure include a partially halogenated hydrocarbon, dichloromethane, chloroform, ethylene chloride, 1,2-dichloroethane, vinyl chloride, chlorodifluoromethane, and the like, or combinations thereof.

In an embodiment, the TCA treated barium titanate can be contacted with a first casting solvent to form a first casting solvent solution. For example, the TCA treated barium titanate can be added to the first casting solvent under stirring (e.g., magnetically stirring, agitating). In an embodiment, the first casting solvent solution can be stirred for a time period of from about 1 minute to about 2 hours, alternatively from about 5 minutes to about 1 hour, or alternatively from about 10 minutes to about 30 minutes, to provide for uniform mixing of the TCA treated barium titanate in casting solvent. In such embodiment, the first casting solvent solution can be further dispersed to facilitate breaking any agglomerates of particles, and to provide a uniform dispersion of TCA treated barium titanate in the first casting solvent solution. In an embodiment, the first casting solvent solution can be dispersed (e.g., sonicated) for a time period of from about 5 minutes to about 3 hours, alternatively from about 10 minutes to about 2 hours, or alternatively from about 15 minutes to about 1 hour.

In an embodiment, the first casting solvent solution can comprise barium titanate in an amount of from about 1 wt. % to about 65 wt. %, alternatively from about 5 wt. % to about 40 wt. %, or alternatively from about 10 wt. % to about 25 wt. %, based on the total weight of the first casting solvent solution.

In an embodiment, the PEI can be contacted with a second casting solvent to form a second casting solvent solution. For example, the PEI can be added to the second casting solvent under stirring (e.g., magnetically stirring, agitating). In an embodiment, the second casting solvent solution can be stirred for a time period of from about 1 minute to about 2 hours, alternatively from about 5 minutes to about 1 hour, or alternatively from about 10 minutes to about 30 minutes, to provide for uniform mixing of the TCA treated barium titanate in casting solvent.

In some embodiments, the first casting solvent and the second casting solvent can be the same. In other embodiments, the first casting solvent and the second casting solvent can be different.

In an embodiment, at least a portion of the first casting solvent solution can be contacted with at least a portion of the second casting solvent solution to form the polymer composite casting solution. In some embodiments, the first casting solvent solution can be added to the second casting solvent solution. In other embodiments, the second casting solvent solution can be added to the first casting solvent solution. For example, the second casting solvent solution can be added to the first casting solvent solution under stirring (e.g., magnetically stirring, agitating). In an embodiment, the polymer composite casting solution can be stirred for a time period of from about 1 minute to about 2 hours, alternatively from about 5 minutes to about 1 hour, or alternatively from about 10 minutes to about 30 minutes, to provide for uniform mixing of the TCA treated barium titanate and the PEI in casting solvent. In such embodiment, the polymer composite casting solution can be further dispersed to facilitate breaking any agglomerates of particles, and to provide an uniform dispersion of TCA treated barium titanate and PEI in the casting solvent (e.g., to improve the dispersion of TCA treated barium titanate in the polymer). In an embodiment, the polymer composite casting solution can be dispersed (e.g., sonicated) for a time period of from about 5 minutes to about 3 hours, alternatively from about 10 minutes to about 2 hours, or alternatively from about 15 minutes to about 1 hour.

In an embodiment, the polymer composite casting solution can comprise TCA treated barium titanate and PEI in a weight ratio of from about 0.25:1 to about 2:1, alternatively from about 0.5:1 to about 1.5:1, or alternatively from about 0.75:1 to about 1.25:1.

In an embodiment, a method of making a solvent cast polymer composite film can comprise casting at least a portion of the polymer composite casting solution to form the solvent cast polymer composite film. The solvent cast polymer composite films can be prepared from a polymer composite casting solution by using any suitable methodology.

In an embodiment, at least a portion of the polymer composite casting solution can be cast onto a casting substrate to form a solvent cast polymer composite solution. The polymer composite casting solution can be cast into a film by using a film applicator. The polymer composite casting solution can take on a form having a length, width and depth on a surface of the casting substrate.

In some embodiments, the solvent cast polymer composite solution can be allowed to air dry prior to curing, for example air dry at ambient pressure and temperature, for a time period of from about 6 hours to about 48 hours, alternatively from about 8 hours to about 24 hours, or alternatively from about 10 hours to about 16 hours. As will be appreciated by one of skill in the art, and with the help of this disclosure, air drying the solvent cast polymer composite solution provides an opportunity for a portion of the casting solvent to evaporate.

In an embodiment, at least a portion of the solvent cast polymer composite solution can be cured to form the solvent cast polymer composite film, for example by evaporating at least a portion of the casting solvent of the solvent cast polymer composite solution. As will be appreciated by one of skill in the art, and with the help of this disclosure, evaporating the casting solvent of the solvent cast polymer composite solution can be facilitated by increasing the temperature (e.g., heating) and decreasing the pressure (e.g., applying a vacuum).

In an embodiment, the solvent cast polymer composite solution can be cured (e.g., dried under vacuum) at a temperature of from about 50° C. to about 120° C., alternatively from about 60° C. to about 110° C., or alternatively from about 70° C. to about 90° C., and under vacuum.

In an embodiment, the solvent cast polymer composite solution can be cured for a time period of from about 1 hour to about 48 hours, alternatively from about 4 hours to about 24 hours, or alternatively from about 6 hours to about 16 hours. In an embodiment, the solvent cast polymer composite solution can be cured for an amount of time effective to remove a desired amount of casting solvent from the solvent cast polymer composite solution to form the solvent cast polymer composite film. For example, equal to or greater than about 90%, alternatively equal to or greater than about 95%, alternatively equal to or greater than about 99% of the casting solvent can be removed from the solvent cast polymer composite solution to form the solvent cast polymer composite film. Methods for preparing solvent cast polymer composite films are described in more detail in U.S. Patent Application No. 20080044684 A1, which is incorporated by reference herein in its entirety.

In an embodiment, the solvent cast polymer composite film of the present disclosure can comprise TCA treated barium titanate and PEI, wherein the solvent cast polymer composite film has a top surface and a bottom surface, wherein a difference between a top surface barium concentration and a bottom surface barium concentration is less than about 30%, alternatively less than about 25%, or alternatively less than about 20%, and wherein the surface barium concentration is determined by elemental analysis via scanning electron microscopy (SEM). A surface concentration of a certain element (e.g., barium) can refer to the wt. % of that respective element in a predefined surface area, wherein the surface concentrations of all elements present on the predefined surface area add up to 100 wt. %.

SEM coupled with energy dispersive X-ray spectroscopy (SEM/EDX) is the best known and most widely-used of the surface analytical techniques, and it can generate high resolution images of surface topography, with excellent depth of field, by using a highly-focused, scanning (primary) electron beam. The primary electrons can enter a surface with an energy of 0.5-30 kV and generate many low energy secondary electrons in a manner that is largely governed by the surface topography of the sample. In addition to low energy secondary electrons, backscattered electrons and X-rays are also generated by primary electron bombardment. The intensity of backscattered electrons can be correlated to the atomic number of the element within the sampling surface area, and as such elemental information (e.g., surface elemental concentration) can be obtained with respect to the scanned surface.

In an embodiment, the solvent cast polymer composite film of the present disclosure can have a top surface and a bottom surface. Generally, barium titanate tends to settle in films, resulting in a non-uniform distribution of barium titanate across a thickness of the film, e.g., a top surface barium concentration can be very different (usually lower, if the top surface is with respect to the position in which the film was dried) from a bottom surface barium concentration, due to barium titanate settling within the film. Barium titanate has a density of about 6 g/cm³, and consequently has the tendency to settle.

In an embodiment, the solvent cast polymer composite film of the present disclosure can be characterized by a difference between a top surface barium concentration and a bottom surface barium concentration that is reduced by at least about 50%, alternatively by at least about 60%, or alternatively by at least about 75%, when compared to the difference between a top surface barium concentration and a bottom surface barium concentration of an otherwise similar solvent cast polymer composite film comprising PEI and barium titanate that has not been treated with TCA.

In an embodiment, a partial top surface barium concentration of any 1 μm² of the top surface of the solvent cast polymer composite film can differ by less than about 20%, alternatively by less than about 15%, or alternatively by less than about 10% from the top surface barium concentration. As will be appreciated by one of skill in the art, and with the help of this disclosure, the top surface barium concentration is an average concentration across the top surface of the film. The lower the difference between any 1 μm² of the top surface of the solvent cast polymer composite film and the top surface barium concentration, the more uniform the distribution of barium titanate in the film.

In an embodiment, a partial bottom surface barium concentration of any 1 μm² of the bottom surface of the solvent cast polymer composite film can differ by less than about 20%, alternatively by less than about 15%, or alternatively by less than about 10% from the bottom surface barium concentration. As will be appreciated by one of skill in the art, and with the help of this disclosure, the bottom surface barium concentration is an average concentration across the bottom surface of the film. The lower the difference between any 1 μm² of the bottom surface of the solvent cast polymer composite film and the bottom surface barium concentration, the more uniform the distribution of barium titanate in the film.

In an embodiment, the solvent cast polymer composite film of the present disclosure can comprise TCA treated barium titanate and PEI in a weight ratio of from about 0.25:1 to about 2:1, alternatively from about 0.5:1 to about 1.5:1, or alternatively from about 0.75:1 to about 1.25:1.

In an embodiment, the solvent cast polymer composite film of the present disclosure can have a thickness of from about 0.1 microns to about 1,000 microns, alternatively from about 0.5 microns to about 500 microns, or alternatively from about 1 micron to about 250 microns.

In an embodiment, the solvent cast polymer composite film of the present disclosure can be piezoelectric. Generally, a piezoelectric material is a material that exhibits the piezoelectric effect, i.e., the reversible ability of certain materials to generate an electric charge in response to applied mechanical stress, such as pressure. Piezoelectric materials are currently used in a wide variety of applications, spanning from industrial and manufacturing applications, to the automotive industry and telecommunications, as well as in medical instruments and computing devices.

In an embodiment, the solvent cast polymer composite film of the present disclosure can be characterized by a dielectric breakdown strength of equal to or greater than about 600 KV/cm, alternatively equal to or greater than about 650 KV/cm, alternatively equal to or greater than about 700 KV/cm, or alternatively equal to or greater than about 725 KV/cm. The terms “dielectric breakdown strength” and “breakdown strength” can be used interchangeably and refer to the maximum electric field strength that a material can withstand intrinsically without breaking down, for example, without experiencing failure of its insulating properties. For example, the breakdown strength of an electrical insulator can be measured by applying a rising voltage to a sample of the material of known thickness until it fails, and it can be calculated as the ratio between the voltage required for breakdown and the thickness of the material at the point where breakdown occurred, and it is usually expressed in kV/mm or KV/cm.

In an embodiment, the solvent cast polymer composite film of the present disclosure can be characterized by a dielectric breakdown strength that is increased by at least 25%, alternatively by at least 30%, or alternatively by at least 35%, when compared to a dielectric breakdown strength of an otherwise similar solvent cast polymer composite film comprising polyetherimide and barium titanate that has not been treated with TCA.

In an embodiment, the solvent cast polymer composite film of the present disclosure can be characterized by a remnant polarization of equal to or greater than about 2.5 μC/cm², alternatively equal to or greater than about 3.0 μC/cm², or alternatively equal to or greater than about 4.0 μC/cm². Generally, the remnant polarization can be defined as the remaining polarization that is still present in a material after an applied external electric field is removed (e.g., at zero field). Materials with enhanced remnant polarization, such as the solvent cast polymer composite films of the present disclosure, are suitable for applications in memory devices, piezoelectric sensors, actuators, transducer devices, and the like, or combinations thereof.

In an embodiment, the solvent cast polymer composite film of the present disclosure can be characterized by a remnant polarization that is increased by at least 50%, alternatively by at least 60%, or alternatively by at least 75%, when compared to a remnant polarization of an otherwise similar solvent cast polymer composite film comprising polyetherimide and barium titanate that has not been treated with TCA.

In an embodiment, the solvent cast polymer composite film of the present disclosure can be characterized by a maximum polarization of equal to or greater than about 3.0 μC/cm², alternatively equal to or greater than about 4.0 μC/cm², or alternatively equal to or greater than about 5.0 μC/cm². Generally, the maximum polarization can be defined as the polarization that is present in a material while a maximum field is applied (e.g., at maximum field). Generally, the maximum field is less than the breakdown field, e.g., if the field is increased beyond the maximum field, the breakdown will occur. For example, to obtain maximum polarization, an applied electric field should be just before any breakdown field. Without wishing to be limited by theory, with an increase in the breakdown field, materials can be polarized more.

In an embodiment, the solvent cast polymer composite film of the present disclosure can be characterized by a maximum polarization that is increased by at least 50%, alternatively by at least 60%, or alternatively by at least 75%, when compared to a maximum polarization of an otherwise similar solvent cast polymer composite film comprising polyetherimide and barium titanate that has not been treated with TCA.

In an embodiment, the solvent cast polymer composite film of the present disclosure can be formed in a variety of article. For example, the solvent cast polymer composite film can be incorporated in a display screen for haptic feedback in a user device, such as an electronic device, a mobile device, etc. (e.g., a touchscreen). Devices that include piezoelectric films are described in more detail in U.S. Provisional Application Nos. 62/185,506; 62/185,515; 62/141,513; and 62/247,482; each of which is incorporated by reference herein in its entirety.

In an embodiment, a solvent cast piezoelectric polymer composite film can comprise PEI and TCA treated barium titanate particles; wherein the TCA treated barium titanate particles are characterized by a size of less than about 800 nm; wherein the PEI and TCA treated barium titanate particles are present in the film in a weight ratio of about 1:1; wherein the TCA treated barium titanate comprises about 0.1 wt. % TCA, based on the total weight of the barium titanate; wherein the film has a dielectric breakdown strength of equal to or greater than about 725 KV/cm; wherein the film has a remnant polarization of equal to or greater than about 4.0 μC/cm²; and wherein the film has a maximum polarization of equal to or greater than about 5.0 μC/cm². In such embodiment, the TCA comprises titanium (IV) 2,2(bis 2-propenolatomethyl)butanolato, tris(dioctyl)phosphato-O.

In an embodiment, a method of making a solvent cast polymer composite film can comprise (a) contacting barium titanate, a TCA and isopropanol to form a barium titanate and TCA solution, wherein the TCA comprises titanium (IV) 2,2(bis 2-propenolatomethyl)butanolato, tris(dioctyl)phosphato-O; (b) sonicating at least a portion of the barium titanate and TCA solution to form TCA treated barium titanate, wherein the TCA treated barium titanate comprises about 0.1 wt. % TCA, based on the total weight of the barium titanate; (c) drying the TCA treated barium titanate at a temperature of from about 70° C. to about 90° C.; (d) contacting at least a portion of the TCA treated barium titanate with PEI and dichloromethane to form a polymer composite casting solution; (e) casting at least a portion of the polymer composite casting solution onto a casting substrate to form a solvent cast polymer composite solution; and (f) curing at least a portion of the solvent cast polymer composite solution at a temperature of from about 70° C. to about 90° C. to form the solvent cast polymer composite film, wherein the PEI and TCA treated barium titanate particles are present in the film in a weight ratio of about 1:1.

In an embodiment, solvent cast polymer composite films comprising TCA treated barium titanate and PEI, and methods of making same, as disclosed herein can advantageously display improvements in one or more film and/or method characteristics when compared to otherwise similar solvent cast polymer composite film comprising PEI and barium titanate that has not been treated with TCA, and methods of making same. In an embodiment, the solvent cast polymer composite films as disclosed herein can advantageously display improved (e.g., higher) dielectric breakdown strength, and thus increased remnant polarization and maximum polarization when compared to otherwise similar solvent cast polymer composite film comprising PEI and barium titanate that has not been treated with TCA.

In an embodiment, a method of making a solvent cast polymer composite film as disclosed herein can advantageously lead to films with a more uniform dispersion or distribution of barium titanate within the film, when compared to an otherwise similar method of preparing a solvent cast polymer composite film that lacks a step of dispersing at least a portion of the barium titanate and TCA solution to form the TCA treated barium titanate. Additional advantages of the solvent cast polymer composite films comprising TCA treated barium titanate and PEI, and methods of making same, as disclosed herein can be apparent to one of skill in the art viewing this disclosure.

### EXAMPLES

The subject matter having been generally described, the following examples are given as particular embodiments of the disclosure and to demonstrate the practice and advantages thereof. It is understood that the examples are given by way of illustration and are not intended to limit the specification of the claims to follow in any manner.

### Example 1

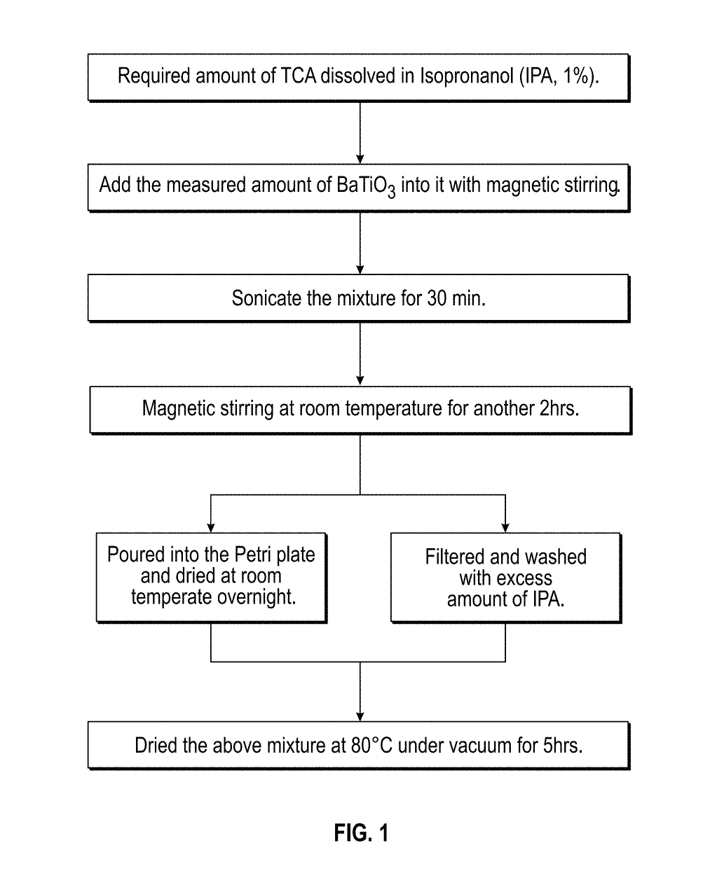

TCA treated barium titanate was prepared according to the process sequence of FIG. 1, wherein barium titanate was surface functionalized with a TCA. Barium titanate particles (particle size<2 μm from Sigma-Aldrich) were treated with TCA (KEN-REACT coupling agent LICA 12 from Kenrich Petrochemicals, Inc. USA). The concentration of the coupling agent was varied from 0.05, 0.2, 0.5, 1.0 and 5.0 wt. %, based on the total weight of the barium titanate. KEN-REACT coupling agent LICA 12 comprises titanium (IV) 2,2(bis 2-propenolatomethyl)butanolato, tris(dioctyl)phosphato-O.

### Example 2

Barium titanate samples, both treated with TCA and untreated, were subjected to various analyses. Sample #1 (a control sample) contained untreated barium titanate. Sample #2 was TCA treated barium titanate prepared as described in Example 1, wherein the TCA and the barium titanate were mixed in a ratio of 5 wt. % TCA, based on the total weight of the barium titanate, and wherein the TCA treated barium titanate was poured in a Petri dish and dried overnight, without a washing step. Sample #3 was TCA treated barium titanate prepared as described in Example 1, wherein the TCA and the barium titanate were mixed in a ratio of 5 wt. % TCA, based on the total weight of the barium titanate, and wherein the TCA treated barium titanate was filtered and washed once with excess isopropanol, and then dried.

TCA treated barium titanate unwashed and washed samples were characterized by Fourier Transform Infrared (FTIR) spectroscopy to evaluate the adhesion of the coupling agent (TCA) on the surface of the barium titanate particles. A KBr pellet was prepared before FTIR scans. The number of scans was 64, and the scan range was 500-4000 cm⁻¹, on a Perkin Elmer instrument.

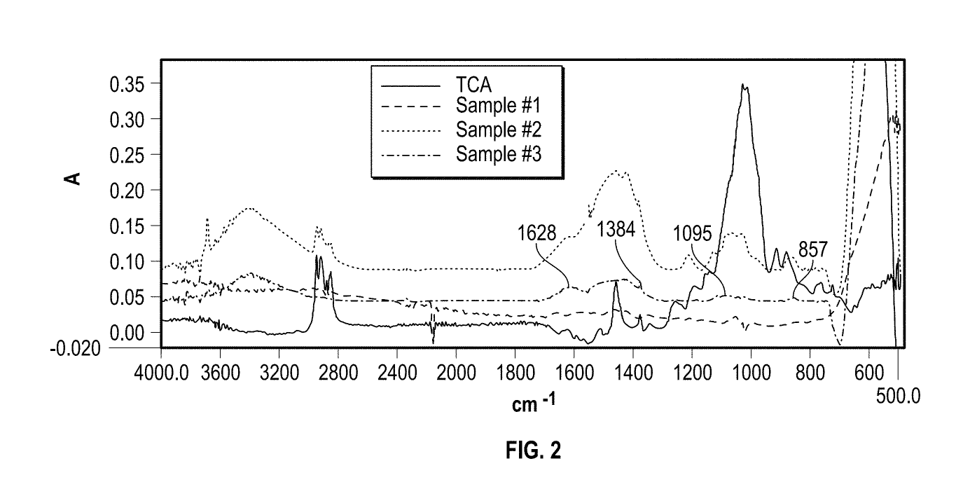

FIG. 2 displays the FTIR spectra for TCA, and samples #1, #2, and #3. The observed small FTIR peaks at 1628, 1348, 1095 (P=0 stretching) and 857 cm⁻¹ for 0.5% TCA in BaTiO₃ sample indicates peaks from TCA molecule. The peaks appeared even after samples were washed, which confirms the attachment of TCA on the surface of BaTiO₃ particles.

### Example 3

Barium titanate samples, both treated with TCA and untreated, were subjected to various analyses. Sample #1 (a control sample) contained untreated barium titanate. Sample #4 was TCA treated barium titanate prepared as described in Example 1, wherein the TCA and the barium titanate were mixed in a ratio of 1 wt. % TCA, based on the total weight of the barium titanate, and wherein the TCA treated barium titanate was poured in a Petri dish and dried overnight, without a washing step. Sample #5 was TCA treated barium titanate prepared as described in Example 1, wherein the TCA and the barium titanate were mixed in a ratio of 1 wt. % TCA, based on the total weight of the barium titanate, and wherein the TCA treated barium titanate was filtered and washed once with excess isopropanol, and then dried. Sample #6 was TCA treated barium titanate prepared as described in Example 1, wherein the TCA and the barium titanate were mixed in a ratio of 1 wt. % TCA, based on the total weight of the barium titanate, and wherein the TCA treated barium titanate was filtered and washed twice with excess isopropanol, and then dried.

TCA treated barium titanate unwashed and washed samples were characterized by thermo-gravimetric (TGA) analysis to evaluate the adhesion of the coupling agent (TCA) on the surface of the barium titanate particles. A Perkin-Elmer TGA m/c was used, at a scan rate of 10° C. per min in air atmosphere, and within a temperature range of 50° C. to 800° C.

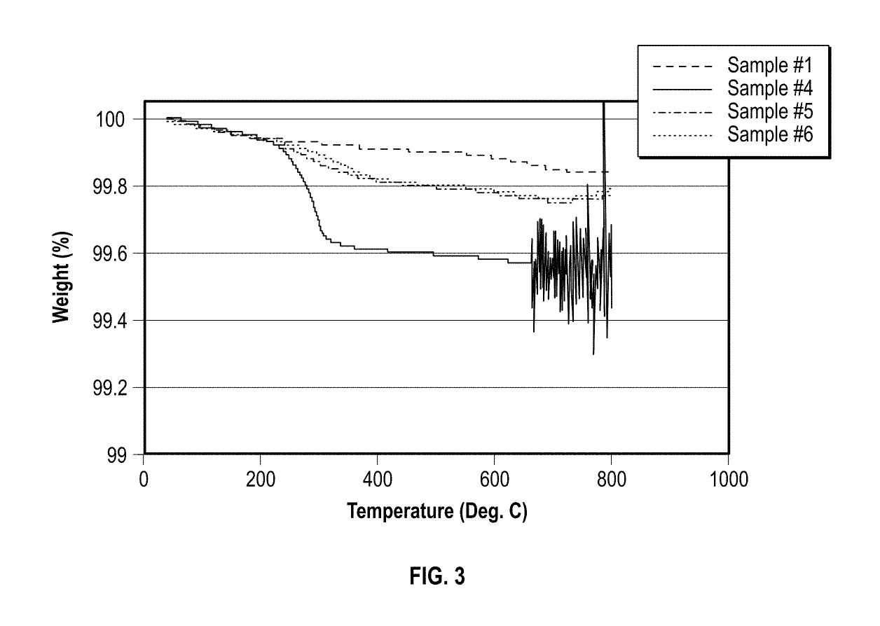

FIG. 3 displays the FTIR spectra for TCA, and samples #1, #4, #5, and #6. The percentage adhesion of coupling agent on BaTiO₃ particle surface for without, single and double wash with excess solvent (isopropanol) was as follows: 0.22% for sample #4 (without wash); 0.07% for sample #5 (single wash); and 0.05% for sample #6 (double wash). The data in FIG. 3 indicate that the optimum adhesion of the coupling agent (TCA) on the barium titanate surface is around 0.2% before wash with excess solvent (isopropanol). During washing, loosely bound TCA has been removed. Without wishing to be limited by theory, it can be concluded that after washing the remaining TCA is physically and/or chemically attached to the surface of the BaTiO₃.

### Example 4

Various solvent cast polymer composite films were prepared. The TCA treated barium titanate of Examples 1, 2, and 3 were used to form solvent cast polymer composite films comprising TCA treated barium titanate and PEI. The films were prepared as follows.

PEI powder was dissolved in dichloromethane (DCM). TCA treated BaTiO₃ powder was also dispersed in DCM separately. The TCA treated BaTiO₃ powder was poured very slowly into the solvent (e.g., DCM) with magnetic stirring. After 15 minutes of magnetic stirring, the dispersion was kept under sonication for 30 min at room temperature. Afterwards, this BaTiO₃ dispersion was added slowly into the polymer solution under continued magnetic stirring for 15 min. Thereafter, the BaTiO₃ dispersed polymer solution was again kept under sonication for another 30 min and was finally cast into a film by a film applicator. The film was kept overnight at room temperature and subsequently dried at 80° C. for 12 hours under vacuum.

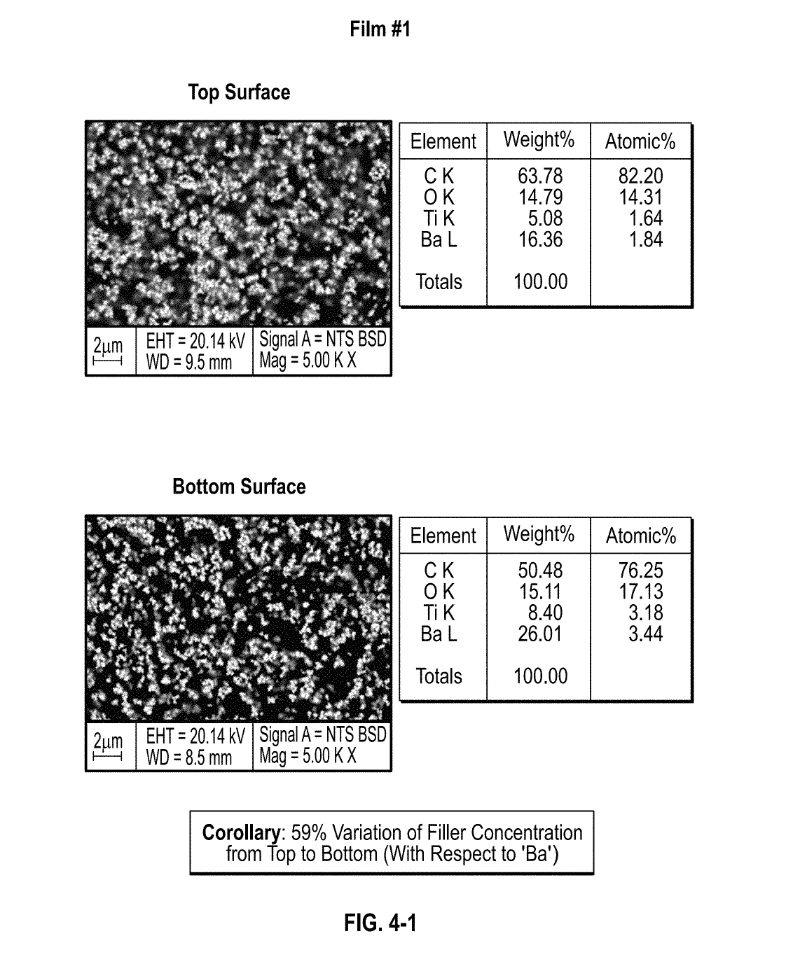

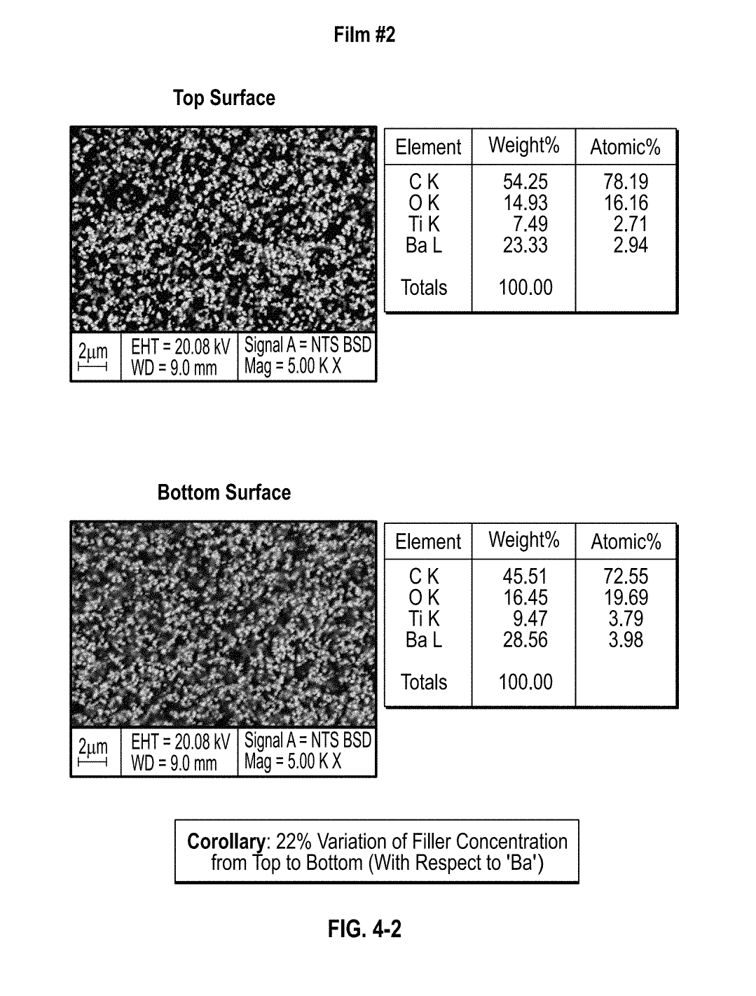

Film #1 was prepared by using sample #1, wherein the PEI and the BaTiO₃ were mixed in a 1:1 weight ratio; and film #2 was prepared by using a sample prepared as described in Example 2, wherein the PEI and the TCA treated BaTiO₃ were mixed in a 1:1 weight ratio. The top surface and the bottom surface of the films were subjected to scanning electron microscopy (SEM) imaging and analysis, and the results are displayed in FIGS. 4-1 and 4-2. A ZEISS SEM was used, at a magnification of 5.00 k×.

The images in FIGS. 4-1 and 4-2 display the particle dispersion at the upper and bottom surface of the cast film. The variation in particle concentration from the top surface to the bottom surface was drastically reduced (from 59% for film #1 to 22% for film #2, when calculated with reference to BaTiO₃) when TCA treated BaTiO₃ particles were incorporated into the polymer matrix (film #2). Without wishing to be limited by theory, the organic part of the TCA molecule (which is attached to the BaTiO₃ surface) interacts with the PEI matrix in a much better way in film #2, and the particles held adhered with less chance of falling down at the bottom of the film, which is not the case for film #1, where BaTiO₃ was not treated with TCA. Thus film #2 has less variation of particle distribution as compared to film #1.

### Example 5

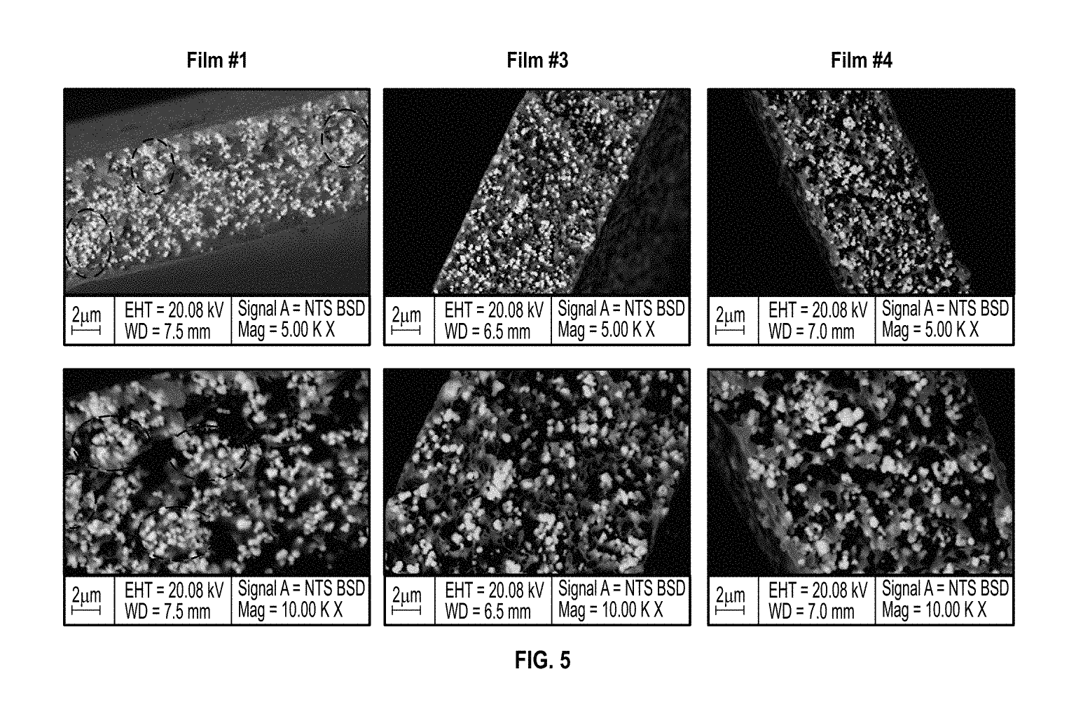

Various solvent cast polymer composite films were prepared. The TCA treated barium titanate of Examples 1, 2, and 3 were used to form solvent cast polymer composite films comprising TCA treated barium titanate and PEI. The films were prepared as described in Example 4. The cross section of the films was imaged by SEM and the results are displayed in FIG. 5. A ZEISS SEM was used, at a magnification of 5.00 k×.

Film #1 was prepared as described in Example 4; film #3 was prepared by using sample #4, wherein the PEI and the TCA treated BaTiO₃ were mixed in a 1:1 weight ratio; and film #4 was prepared by using a sample prepared as described in Example 3, wherein TCA treated barium titanate was prepared as described in Example 1, wherein the TCA and the barium titanate were mixed in a ratio of 1 wt. % TCA, based on the total weight of the barium titanate, wherein the TCA treated barium titanate was filtered and washed with excess isopropanol, and then dried; and wherein the PEI and the TCA treated BaTiO₃ were mixed in a 1:1 weight ratio.

The images in FIG. 5 display the particle dispersion across the cross section of the cast film. Improved dispersion in the cross-section of the composite film was observed in the case of TCA treated BaTiO₃ particles (films #3 and #4). Without wishing to be limited by theory, the better dispersion of TCA treated BaTiO₃ as compared to untreated particles can be due to the better mixing ability of the surface adhered organic portion (which lowers the surface energy of the inorganic particles and provides better compatibility with the PEI matrix) of the TCA molecule onto the BaTiO₃ particle surface.

### Example 6

Various solvent cast polymer composite films were prepared. The TCA treated barium titanate of Examples 1, 2, and 3 were used to form solvent cast polymer composite films comprising TCA treated barium titanate and PEI. The films were prepared as described in Example 4. The films were coated with gold and palladium by sputtering.

Film #1 was prepared as described in Example 4; film #5 was prepared by using a TCA treated BaTiO₃ containing 0.2% TCA, based on the weight of the barium titanate, wherein the PEI and the TCA treated BaTiO₃ were mixed in a 1:1 weight ratio; and film #6 was prepared by using a TCA treated BaTiO₃ containing 0.5% TCA, based on the weight of the barium titanate, wherein the PEI and the TCA treated BaTiO₃ were mixed in a 1:1 weight ratio.

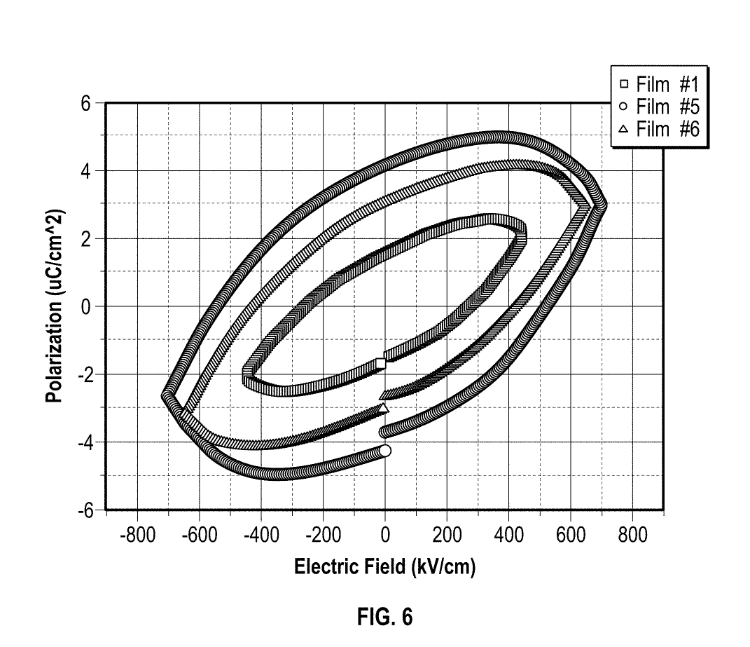

The films were subjected to polarization experiments, and the resulting data is displayed in Table 1 and FIG. 6. All polarization measurements were performed at room temperature. P-E hysteresis plots (polarization, P [μC/cm²] vs. applied electric field, E [KV/cm]) are shown in FIG. 6 and result details are given in Table 1.

TABLE 1

| | Maximum | | | |
|---|---|---|---|---|
| | electric field | Breakdown | Remnant | Max. |
| | (KV/cm) where the | field | polarization | Polarization |
| Samples | hysteresis is plotted | (KV/cm) | (μC/cm²) | (μC/cm²) |
| Film #1 | 450 | 500 | 1.6 | 2.5 |
| Film #5 | 720 | 740 | 4.3 | 5.2 |
| Film #6 | 650 | 670 | 3.2 | 4.1 |

The data in Table 1 and FIG. 6 indicate that addition of the coupling agent (TCA) improves breakdown strength and enhances the remnant polarization, which is a good indication that these composite films can be subjected to a poling process with higher electric field to obtain a higher piezoelectric constant value. However, the optimum concentration of TCA appears to be about 0.2%, based on the weight of BaTiO₃. Upon increasing TCA concentration, the effect of improving breakdown strength also goes down, probably due to an increased plasticizing effect of the coupling agent into the polymer matrix (which is not the case for the lower coupling agent concentration). Using an optimum level of coupling agent (e.g., TCA) provides improved dispersion of inorganic BaTiO₃ particles. In other words, the use of the coupling agent reduces local agglomerations, which agglomerations can act as a defect in the composite structure and can respond to early electrical breakdown during polarization. Thus, a structure (e.g., a film) containing such agglomerations will not be able pole to its fullest extent to provide higher piezoelectric constants. The use of coupling agent (e.g., TCA) thus provides an extra arrangement in the composite structure to obtain better piezoelectricity.

For the purpose of any U.S. national stage filing from this application, all publications and patents mentioned in this disclosure are incorporated herein by reference in their entireties, for the purpose of describing and disclosing the constructs and methodologies described in those publications, which might be used in connection with the methods of this disclosure. Any publications and patents discussed herein are provided solely for their disclosure prior to the filing date of the present application. Nothing herein is to be construed as an admission that the inventors are not entitled to antedate such disclosure by virtue of prior invention.

In any application before the United States Patent and Trademark Office, the Abstract of this application is provided for the purpose of satisfying the requirements of 37 C.F.R. §1.72 and the purpose stated in 37 C.F.R. §1.72(b) “to enable the United States Patent and Trademark Office and the public generally to determine quickly from a cursory inspection the nature and gist of the technical disclosure.” Therefore, the Abstract of this application is not intended to be used to construe the scope of the claims or to limit the scope of the subject matter that is disclosed herein. Moreover, any headings that can be employed herein are also not intended to be used to construe the scope of the claims or to limit the scope of the subject matter that is disclosed herein. Any use of the past tense to describe an example otherwise indicated as constructive or prophetic is not intended to reflect that the constructive or prophetic example has actually been carried out.

The present disclosure is further illustrated by the following examples, which are not to be construed in any way as imposing limitations upon the scope thereof. On the contrary, it is to be clearly understood that resort can be had to various other aspects, embodiments, modifications, and equivalents thereof which, after reading the description herein, can be suggest to one of ordinary skill in the art without departing from the spirit of the present invention or the scope of the appended claims.

### ADDITIONAL DISCLOSURE

A first aspect, which is a method of making a solvent cast polymer composite film comprising (a) contacting barium titanate, a titanate coupling agent (TCA) and a mixing solvent to form a barium titanate and TCA solution; (b) dispersing at least a portion of the barium titanate and TCA solution to form TCA treated barium titanate; (c) contacting at least a portion of the TCA treated barium titanate with a polyetherimide and a casting solvent to form a polymer composite casting solution; (d) casting at least a portion of the polymer composite casting solution onto a casting substrate to form a solvent cast polymer composite solution; and (e) curing at least a portion of the solvent cast polymer composite solution to form the solvent cast polymer composite film.

A second aspect, which is the method of the first aspect, wherein the step (a) of contacting barium titanate, a TCA and a mixing solvent comprises adding the barium titanate to a solution of TCA in the mixing solvent to form the barium titanate and TCA solution.

A third aspect, which is the method of any one of the first and the second aspects, wherein the step (b) of dispersing at least a portion of the barium titanate and TCA solution comprises sonicating the at least a portion of the barium titanate and TCA solution.

A fourth aspect, which is the method of any one of the first through the third aspects, wherein the step (b) of dispersing at least a portion of the barium titanate and TCA solution comprises forming a TCA treated barium titanate solution, wherein the TCA treated barium titanate solution comprises TCA treated barium titanate, uncoupled TCA, and mixing solvent.

A fifth aspect, which is the method of the fourth aspect, wherein at least a portion of the TCA treated barium titanate solution is filtered to yield a raw TCA treated barium titanate and a first spent mixing solvent, wherein the raw TCA treated barium titanate comprises TCA treated barium titanate and uncoupled TCA.

A sixth aspect, which is the method of the fifth aspect, wherein the raw TCA treated barium titanate is washed with mixing solvent to yield the TCA treated barium titanate and a second spent mixing solvent, wherein the second spent mixing solvent comprises at least a portion of the uncoupled TCA of the raw TCA treated barium titanate.

A seventh aspect, which is the method of the sixth aspect, wherein the TCA treated barium titanate is further dried.

An eighth aspect, which is the method of any one of the first through the seventh aspects, wherein the mixing solvent comprises an alcohol, methanol, ethanol, propanol, isopropanol, butanol, pentanol, or combinations thereof.

A ninth aspect, which is the method of any one of the first through the eighth aspects, wherein the step (c) of contacting at least a portion of the TCA treated barium titanate with a polyetherimide and a casting solvent comprises (i) contacting the TCA treated barium titanate with a first casting solvent to form a first casting solvent solution; (ii) contacting the polyetherimide with a second casting solvent to form a second casting solvent solution; and (iii) contacting at least a portion of the first casting solvent solution with at least a portion of the second casting solvent solution to form the polymer composite casting solution.

A tenth aspect, which is the method of the ninth aspect, wherein the first casting solvent and the second casting solvent are the same.

An eleventh aspect, which is the method of any one of the first through the tenth aspects, wherein the first casting solvent solution is sonicated prior to contacting with the second casting solvent solution.

A twelfth aspect, which is the method of any one of the first through the eleventh aspects, wherein the casting solvent comprises a partially halogenated hydrocarbon, dichloromethane, chloroform, ethylene chloride, 1,2-dichloroethane, vinyl chloride, chlorodifluoromethane, or combinations thereof.

A thirteenth aspect, which is the method of any one of the first through the twelfth aspects, wherein the polymer composite casting solution is sonicated prior to the step (d) of casting at least a portion of the polymer composite casting solution.

A fourteenth aspect, which is the method of any one of the first through the thirteenth aspects, wherein the step (e) of curing at least a portion of the solvent cast polymer composite solution comprises drying under vacuum at least a portion of the solvent cast polymer composite solution at a temperature of from about 70° C. to about 90° C.

A fifteenth aspect, which is the method of any one of the first through the fourteenth aspects, wherein the step (e) of curing at least a portion of the solvent cast polymer composite solution comprises evaporating at least a portion of the casting solvent of the solvent cast polymer composite solution.

A sixteenth aspect, which is the method of any one of the first through the fifteenth aspects, wherein the barium titanate and TCA solution comprises TCA in an amount of from about 0.05 wt. % to about 5 wt. %, based on the total weight of the barium titanate.

A seventeenth aspect, which is a solvent cast polymer composite film comprising a titanate coupling agent (TCA) treated barium titanate and polyetherimide, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy.

An eighteenth aspect, which is the solvent cast polymer composite film of the seventeenth aspect, wherein the difference between a top surface barium concentration and a bottom surface barium concentration is reduced by at least 50% when compared to the difference between a top surface barium concentration and a bottom surface barium concentration of an otherwise similar solvent cast polymer composite film comprising polyetherimide and barium titanate that has not been treated with TCA.

A nineteenth aspect, which is the solvent cast polymer composite film of any one of the seventeenth and the eighteenth aspects, wherein a partial top surface barium concentration of any 1 μm² of the top surface differs by less than about 20% from the top surface barium concentration, and wherein a partial bottom surface barium concentration of any 1 μm² of the bottom surface differs by less than about 20% from the bottom surface barium concentration.

A twentieth aspect, which is the solvent cast polymer composite film of any one of the seventeenth through the nineteenth aspects having a thickness of from about 0.1 microns to about 1,000 microns.

A twenty-first aspect, which is the solvent cast polymer composite film of any one of the seventeenth through the twentieth aspects, wherein the TCA treated barium titanate comprises barium titanate particles having an average size of from about 100 nm to about 2 microns.

A twenty-second aspect, which is the solvent cast polymer composite film of any one of the seventeenth through the twenty-first aspects, wherein the TCA treated barium titanate comprises barium titanate particles having an average size of from about 100 nm to about 900 nm.

A twenty-third aspect, which is the solvent cast polymer composite film of any one of the seventeenth through the twenty-second aspects, wherein the TCA comprises neoalkoxy titanates, monoalkoxy titanates, oxyacetate chelate titanates, cycloheteroatom titanates, ethylene chelate titanates, coordinate titanates, or combinations thereof.

A twenty-fourth aspect, which is the solvent cast polymer composite film of the twenty-third aspect, wherein the neoalkoxy titanates comprise titanium (IV) 2,2(bis 2-propenolatomethyl)butanolato, tris(dioctyl)phosphato-O.

A twenty-fifth aspect, which is the solvent cast polymer composite film of any one of the seventeenth through the twenty-fourth aspects, wherein the TCA treated barium titanate comprises TCA in an amount of from about 0.01 wt. % to about 1 wt. %, based on the total weight of the barium titanate.

A twenty-sixth aspect, which is the solvent cast polymer composite film of any one of the seventeenth through the twenty-fifth aspects, wherein the film is piezoelectric.

A twenty-seventh aspect, which is the solvent cast polymer composite film of any one of the seventeenth through the twenty-sixth aspects, wherein the film is characterized by a dielectric breakdown strength of equal to or greater than about 600 KV/cm.

A twenty-eighth aspect, which is the solvent cast polymer composite film of any one of the seventeenth through the twenty-seventh aspects, wherein the film is characterized by a dielectric breakdown strength that is increased by at least 25% when compared to a dielectric breakdown strength of an otherwise similar solvent cast polymer composite film comprising polyetherimide and barium titanate that has not been treated with TCA.

A twenty-ninth aspect, which is the solvent cast polymer composite film of any one of the seventeenth through the twenty-eighth aspects, wherein the film is characterized by a remnant polarization of equal to or greater than about 2.5 μC/cm².

A thirtieth aspect, which is the solvent cast polymer composite film of any one of the seventeenth through the twenty-ninth aspects, wherein the film is characterized by a remnant polarization that is increased by at least 50% when compared to a remnant polarization of an otherwise similar solvent cast polymer composite film comprising polyetherimide and barium titanate that has not been treated with TCA.

A thirty-first aspect, which is the solvent cast polymer composite film of any one of the seventeenth through the thirtieth aspects, wherein the film is characterized by a maximum polarization of equal to or greater than about 3.0 μC/cm².

A thirty-second aspect, which is the solvent cast polymer composite film of any one of the seventeenth through the thirty-first aspects, wherein the film is characterized by a maximum polarization that is increased by at least 50% when compared to a maximum polarization of an otherwise similar solvent cast polymer composite film comprising polyetherimide and barium titanate that has not been treated with TCA.

A thirty-third aspect, which is the solvent cast polymer composite film of any one of the seventeenth through the thirty-second aspects, wherein the film comprises the TCA treated barium titanate and the polyetherimide in a weight ratio of from about 0.25:1 to about 2:1.

A thirty-fourth aspect, which is an article comprising the solvent cast polymer composite film of any one of the seventeenth through the thirty-third aspects.

A thirty-fifth aspect, which is the article of the thirty-fourth aspect, wherein the article is a touchscreen.

A thirty-sixth aspect, which is a method of making a solvent cast polymer composite film comprising (a) contacting barium titanate and a titanate coupling agent (TCA) to form TCA treated barium titanate; (b) contacting at least a portion of the TCA treated barium titanate with a polyetherimide and a casting solvent to form a polymer composite casting solution; and (c) casting at least a portion of the polymer composite casting solution to form the solvent cast polymer composite film, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy.

While aspects and embodiments of the disclosure have been shown and described, modifications thereof can be made without departing from the spirit and teachings of the invention. The embodiments and examples described herein are exemplary only, and are not intended to be limiting. Many variations and modifications of the invention disclosed herein are possible and are within the scope of the invention.

Accordingly, the scope of protection is not limited by the description set out above but is only limited by the claims which follow, that scope including all equivalents of the subject matter of the claims. Each and every claim is incorporated into the specification as an aspect of the present invention. Thus, the claims are a further description and are an addition to the detailed description of the present invention. The disclosures of all patents, patent applications, and publications cited herein are hereby incorporated by reference.

What is claimed is:

1. A method of making a solvent cast polymer composite film comprising:
(a) contacting barium titanate, a titanate coupling agent (TCA) and a mixing solvent to form a barium titanate and TCA solution;
(b) dispersing at least a portion of the barium titanate and TCA solution to form TCA treated barium titanate;
(c) contacting at least a portion of the TCA treated barium titanate with a polyetherimide and a casting solvent to form a polymer composite casting solution;
(d) casting at least a portion of the polymer composite casting solution onto a casting substrate to form a solvent cast polymer composite solution; and
(e) curing at least a portion of the solvent cast polymer composite solution to form the solvent cast polymer composite film.

2. The method of claim 1, wherein the step (b) of dispersing at least a portion of the barium titanate and TCA solution comprises sonicating the at least a portion of the barium titanate and TCA solution.

3. The method of claim 1, wherein the mixing solvent comprises an alcohol, methanol, ethanol, propanol, isopropanol, butanol, pentanol, or combinations thereof.

4. The method of claim 1, wherein the step (c) of contacting at least a portion of the TCA treated barium titanate with a polyetherimide and a casting solvent comprises (i) contacting the TCA treated barium titanate with a first casting solvent to form a first casting solvent solution; (ii) contacting the polyetherimide with a second casting solvent to form a second casting solvent solution; and (iii) contacting at least a portion of the first casting solvent solution with at least a portion of the second casting solvent solution to form the polymer composite casting solution.

5. The method of claim 1, wherein the casting solvent comprises a partially halogenated hydrocarbon, dichloromethane, chloroform, ethylene chloride, 1,2-dichloroethane, vinyl chloride, chlorodifluoromethane, or combinations thereof.

6. The method of claim 1, wherein the polymer composite casting solution is sonicated prior to the step (d) of casting at least a portion of the polymer composite casting solution.

7. The method of claim 1, wherein the step (e) of curing at least a portion of the solvent cast polymer composite solution comprises drying under vacuum at least a portion of the solvent cast polymer composite solution at a temperature of from about 70° C. to about 90° C.

8. The method of claim 1, wherein the barium titanate and TCA solution comprises TCA in an amount of from about 0.05 wt. % to about 5 wt. %, based on the total weight of the barium titanate.

9. A solvent cast polymer composite film comprising a titanate coupling agent (TCA) treated barium titanate and polyetherimide, wherein the solvent cast polymer composite film has a top surface and a bottom surface, wherein a difference between a top surface barium concentration and a bottom surface barium concentration is less than about 30%, and wherein the surface barium concentration is determined by elemental analysis via scanning electron microscopy.

10. The solvent cast polymer composite film of claim 9, wherein the difference between a top surface barium concentration and a bottom surface barium concentration is reduced by at least 50% when compared to the difference between a top surface barium concentration and a bottom surface barium concentration of an otherwise similar solvent cast polymer composite film comprising polyetherimide and barium titanate that has not been treated with TCA.

11. The solvent cast polymer composite film of claim 9, wherein a partial top surface barium concentration of any 1 μm² of the top surface differs by less than about 20% from the top surface barium concentration, and wherein a partial bottom surface barium concentration of any 1 μm² of the bottom surface differs by less than about 20% from the bottom surface barium concentration.

12. The solvent cast polymer composite film of claim 9, wherein the TCA treated barium titanate comprises barium titanate particles having an average size of from about 100 nm to about 2 microns.

13. The solvent cast polymer composite film of claim 9, wherein the TCA comprises neoalkoxy titanates, titanium (IV) 2,2(bis 2-propenolatomethyl)butanolato, tris(dioctyl)phosphato-O, monoalkoxy titanates, oxyacetate chelate titanates, cycloheteroatom titanates, ethylene chelate titanates, coordinate titanates, or combinations thereof.

14. The solvent cast polymer composite film of claim 9, wherein the TCA treated barium titanate comprises TCA in an amount of from about 0.01 wt. % to about 1 wt. %, based on the total weight of the barium titanate.

15. The solvent cast polymer composite film of claim 9, wherein the film is piezoelectric.

16. The solvent cast polymer composite film of claim 9, wherein the film is characterized by a dielectric breakdown strength that is increased by at least 25% when compared to a dielectric breakdown strength of an otherwise similar solvent cast polymer composite film comprising polyetherimide and barium titanate that has not been treated with TCA.

17. The solvent cast polymer composite film of claim 9, wherein the film is characterized by a remnant polarization that is increased by at least 50% when compared to a remnant polarization of an otherwise similar solvent cast polymer composite film comprising polyetherimide and barium titanate that has not been treated with TCA.

18. The solvent cast polymer composite film of claim 9, wherein the film is characterized by a maximum polarization that is increased by at least 50% when compared to a maximum polarization of an otherwise similar solvent cast polymer composite film comprising polyetherimide and barium titanate that has not been treated with TCA.

19. The solvent cast polymer composite film of claim 9, wherein the film comprises the TCA treated barium titanate and the polyetherimide in a weight ratio of from about 0.25:1 to about 2:1.

20. An article comprising the solvent cast polymer composite film of claim 9, wherein the article is a touchscreen.
